(19) United States
(12) Patent Application Publication
(10) Pub. No.: US 2011/0111543 A1
(43) Pub. Date: May 12, 2011

(54) METHOD FOR MANUFACTURING LIQUID CRYSTAL DISPLAY DEVICE

(75) Inventor: Kikuo ONO, Mobara (JP)

(73) Assignee: Hitachi Displays, Ltd.

(21) Appl. No.: 12/942,176

(22) Filed: Nov. 9, 2010

(30) Foreign Application Priority Data
Nov. 9, 2009 (JP) 2009-255699

(51) Int. Cl. H01L 21/306

(52) U.S. Cl. 438/42; 257/E21.219

(57) ABSTRACT

A thin-film transistor including a gate electrode, a drain electrode, and a source electrode is formed. A first insulating film is formed so as to cover the thin-film transistor. A second insulating film is formed on the first insulating film. A transparent conductive film is formed on the second insulating film. An etching resist which is patterned by a photolithography process is formed on the transparent conductive film. A first transparent electrode is formed by patterning the transparent conductive film by a first etching using the etching resist. A penetration hole is formed in the second insulating film at a position above one of the drain electrode and the source electrode by a second etching which is performed using the etching resist on a surface of the second insulating film exposed from the first transparent electrode.

### CROSS-REFERENCE TO RELATED APPLICATION

The present application claims priority from Japanese application JP2009-255699 filed on Nov. 9, 2009, the content of which is hereby incorporated by reference into this application.

### BACKGROUND OF THE INVENTION

1. Field of the Invention

The present invention relates to a method for manufacturing a liquid crystal display device.

2. Description of the Related Art

Liquid crystal display devices have a TFT substrate in which thin-film transistors (TFT) for driving liquid crystals are formed and a color filter substrate in which color filters are formed, and liquid crystals are interposed between the two substrates. In such liquid crystal display devices, a liquid crystal display device which displays images by applying a transverse electric field to the liquid crystals is referred to as an In-Plane Switching (IPS)-mode liquid crystal display device. Such a liquid crystal display device is known to have a wide viewing field angle performance. Moreover, in order to increase the aperture ratio of a liquid crystal display device to decrease the power consumption, the use of an organic insulating film having low permittivity during a TFT deposition process is known.

The TFT substrate of a liquid crystal display device is formed by a plurality of conductive layers and a plurality of insulating layers which are stacked onto each other (see JP-2008-15454A). Each layer is usually formed by deposition and etching.

Etching of a film is performed using an etching resist. The etching resist is patterned by photolithography processes which require a lot of labor and time. Thus, it is desirable to shorten the photolithography processes as much as possible.

### SUMMARY OF THE INVENTION

The present invention aims to shorten the photolithography processes for forming an etching resist.

(1) A liquid crystal display device manufacturing method including the steps of: forming a thin-film transistor including a gate electrode, a drain electrode, and a source electrode; forming a first insulating film so as to cover the thin-film transistor; forming a second insulating film on the first insulating film; forming a transparent conductive film on the second insulating film; forming an etching resist which is patterned by a photolithography process on the transparent conductive film; forming a first transparent electrode by patterning the transparent conductive film by first etching using the etching resist; forming a penetration hole in the second insulating film at a position above one of the drain electrode and the source electrode by second etching which is performed using the etching resist on a surface of the second insulating film exposed from the first transparent electrode; and removing the etching resist. According to this invention, the two processes of patterning the transparent conductive film and forming the penetration hole of the second insulating film are performed using the same etching resist. Thus, the photolithography processes can be reduced.

(2) In the liquid crystal display device manufacturing method according to (1), the first insulating film may be mainly composed of inorganic material, and the second insulating film may be mainly composed of organic material.

(3) In the liquid crystal display device manufacturing method according to (1) or (2), the second etching may be selective etching where the amount of etching on the second insulating film is larger than the amount of etching on the first insulating film, and the second etching may stop before the first insulating film is penetrated.

(4) In the liquid crystal display device manufacturing method according to (3), the step of removing the etching resist may be followed by the steps of: forming a third insulating film on the first transparent electrode, an inner side of the penetration hole, and a surface of the first insulating film exposed to the inner side of the penetration hole; etching the third insulating film and the first insulating film on the inner side of the penetration hole so as to expose one of the drain electrode and the source electrode; and forming a second transparent electrode on a portion of one of the drain electrode and the source electrode exposed from the penetration hole and on the third insulating film.

### BRIEF DESCRIPTION OF THE DRAWINGS

FIG. 1 is an exploded perspective view showing a liquid crystal display device according to an embodiment of the present invention.

FIG. 2 is a top view showing a detailed structure of a portion of a liquid crystal display panel shown in FIG. 1.

FIG. 3 is a sectional view of the liquid crystal display panel taken along the line in FIG. 2.

FIG. 4 is a sectional view of the liquid crystal display panel taken along the line IV-IV in FIG. 2.

FIG. 5 is a schematic top view showing the terminal portions of the liquid crystal display panel shown in FIG. 1 and the vicinities thereof.

FIG. 6 is a sectional view of the liquid crystal display panel taken along the line VI-VI in FIG. 5.

FIG. 7 is a schematic top view showing the terminal portions of the liquid crystal display panel shown in FIG. 1 and the vicinities thereof.

FIG. 8 is a sectional view of the liquid crystal display panel taken along the line VIII-VIII in FIG. 7.

FIGS. 9A to 9C are diagrams illustrating a method for manufacturing a liquid crystal display device according to the embodiment of the present invention.

FIGS. 10A to 10C are diagrams illustrating a method for manufacturing a liquid crystal display device according to the embodiment of the present invention.

FIGS. 11A to 11C are diagrams illustrating a method for manufacturing a liquid crystal display device according to the embodiment of the present invention.

FIGS. 12A to 12C are diagrams illustrating a method for manufacturing a liquid crystal display device according to the embodiment of the present invention.

FIGS. 13A to 13C are diagrams illustrating a method for manufacturing a liquid crystal display device according to the embodiment of the present invention.

FIGS. 14A to 14C are diagrams illustrating a method for manufacturing a liquid crystal display device according to the embodiment of the present invention.

FIGS. 15A to 15C are diagrams illustrating a method for manufacturing a liquid crystal display device according to the embodiment of the present invention.

FIGS. 16A to 16C are diagrams illustrating a method for manufacturing a liquid crystal display device according to the embodiment of the present invention.

FIGS. 17A to 17C are diagrams illustrating a method for manufacturing a liquid crystal display device according to the embodiment of the present invention.

### DETAILED DESCRIPTION OF THE INVENTION

Hereinafter, the embodiment of the present invention will be described with reference to the drawings.

### [Liquid Crystal Display Device]

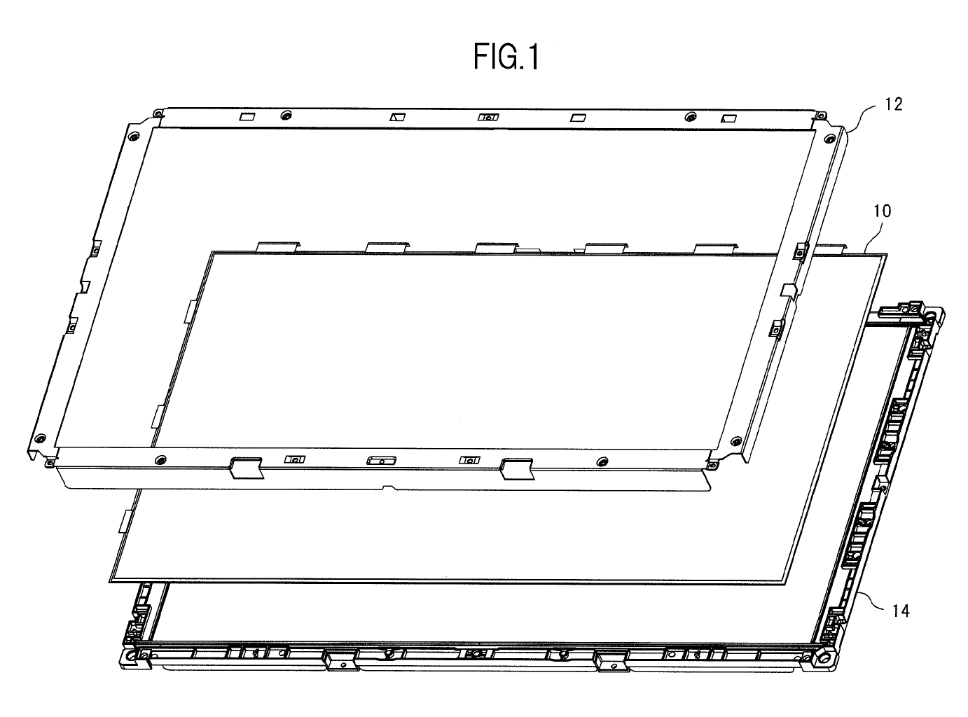

FIG. 1 is an exploded perspective view showing a liquid crystal display device according to an embodiment of the present invention. The liquid crystal display device includes a liquid crystal display panel 10. The liquid crystal display panel 10 is supported by an upper frame 12 and a lower frame 14.

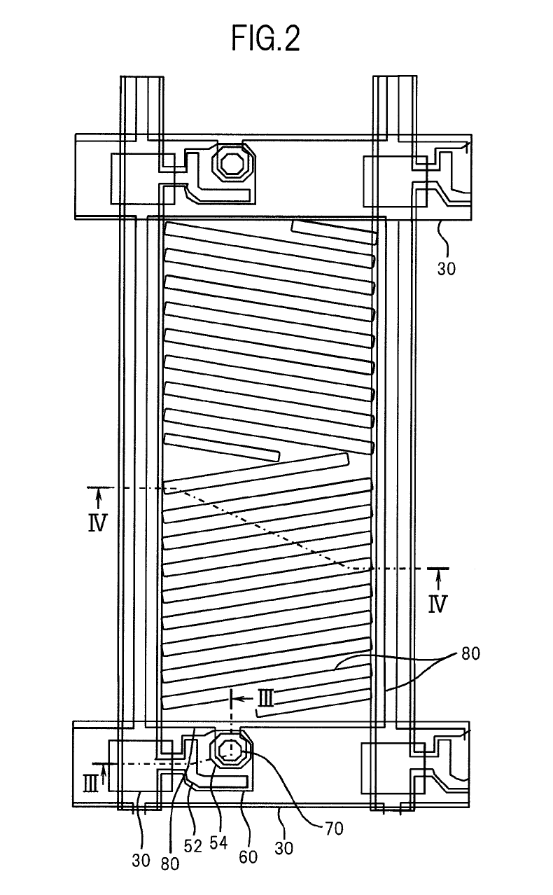

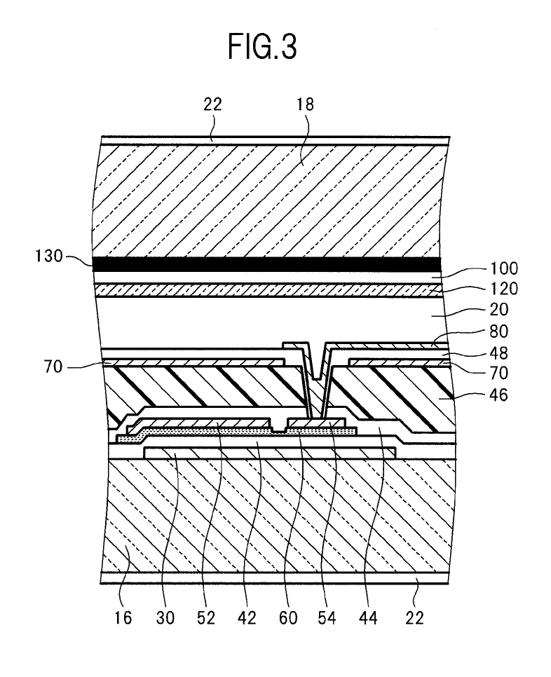

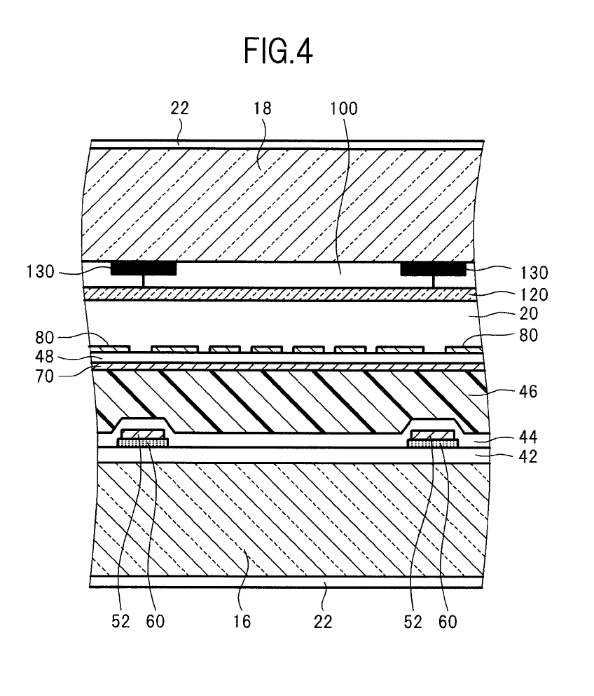

FIG. 2 is a schematic top view showing a portion of the liquid crystal display panel 10 of the liquid crystal display device shown in FIG. 1. FIG. 3 is a sectional view of the liquid crystal display panel 10 taken along the line in FIG. 2. FIG. 4 is a sectional view of the liquid crystal display panel 10 taken along the line IV-IV in FIG. 2

The structure of the liquid crystal display panel 10 is illustrated using the sectional view of FIG. 3. The liquid crystal display panel 10 includes a first substrate 16 and a second substrate 18 (see FIG. 3). The first substrate 16 and the second substrate 18 are transparent substrates (for example, glass substrates). Liquid crystals 20 are disposed between the first substrate 16 and the second substrate 18. The first substrate 16 and the second substrate 18 have a surface on the opposite side of the liquid crystals 20, to which a polarizing plate 22 is attached in a cross-Nicol state.

A thin-film transistor (TFT) is formed on a surface of the first substrate 16 facing the liquid crystals 20. The thin-film transistor is a switch for controlling the driving of the liquid crystals 20. The thin-film transistor is a bottom-gate type transistor in which a gate electrode 30, to which a scanning voltage for control is applied, is disposed on the bottom side. The gate electrode 30 is formed on the first substrate 16. Agate insulating film 42 made from inorganic material (semiconductor oxide such as SiO₂ or semiconductor nitride such as SiN) is formed by a plasma CVD process or the like so as to cover the gate electrode 30. A semiconductor layer 60 made from amorphous silicon or microcrystalline silicon is formed on the gate insulating film 42. A source electrode 54 to which a pixel potential is output and a drain electrode 52, to which a video signal is applied, are formed on the semiconductor layer 60. A first insulating film 44 made from inorganic material (semiconductor oxide such as SiO₂ or semiconductor nitride such as SiN) is formed so as to cover the source electrode 54, the drain electrode 52, and the semiconductor layer 60. The humidity-associated contamination of the semiconductor layer 50 is prevented by the first insulating film 44.

When a gate voltage is applied to the gate electrode 30, the resistance of the semiconductor layer 60 between the drain electrode 52 and the source electrode 54 to which a video signal voltage is applied decreases. As a result, an electric field is generated between a second transparent electrode 80, which is connected to the source electrode 54, and a first transparent electrode 70, to which a common voltage is applied. The electric field is applied to the liquid crystals 20, whereby the transmittance of the liquid crystals 20 is changed, and images are displayed.

A second insulating film 46 is disposed above the thin-film transistor (on the first insulating film 44). The second insulating film 46 is a low-permittivity film having relative permittivity of 4 or lower.

The first transparent electrode 70 is formed on the second insulating film 46. The first transparent electrode 70 has the role of a common electrode on the liquid crystal operation. A third insulating film 48 is formed on the first transparent electrode 70. The third insulating film 48 is constituted by an insulating film made from inorganic material such as SiN. Further, the second transparent electrode 80 is formed on the third insulating film 48. The second transparent electrode has the role of a pixel electrode on a display region. The first transparent electrode 70 or the second transparent electrode 80 may be formed from ITO (Indium Tin Oxide) or indium zinc oxide by a sputtering method or the like.

In a pixel region, the second transparent electrode 80 is connected to the source electrode 54 through the third insulating film 48, the first transparent electrode 70, the second insulating film 46, and an opening of the first insulating film 44. Through this connection, the pixel potential is supplied to the liquid crystals 20. The electric field between the common potential of the second transparent electrode 80 and the first transparent electrode 70 present thereunder with the third insulating film 48 disposed therebetween is applied to the liquid crystals 20, whereby images are displayed.

As shown in FIG. 3, a black matrix 130 is disposed on a surface, close to the liquid crystals 20, of the second substrate 18 which is disposed at a position facing the first substrate 16 with the liquid crystals 20 disposed therebetween. The black matrix 130 is formed from resin including black pigment and carbon. The black matrix 130 prevents light from moving towards a channel region of the semiconductor layer 60. Therefore, the top-view shape of the black matrix 130 is an island-like form or a stripe-like form.

A color filter layer 100 is formed on a side of the black matrix 130 close to the liquid crystals 20. The color filter layer 100 includes a plurality of coloring layers (for example, coloring layers of the three colors red, green, and blue).

On a surface of the second substrate 18 close to the liquid crystals 20, an overcoat film 120 made from organic material is formed so as to cover scratches on the surface thereof. The overcoat film 120 is formed from transparent material so as not to contain contaminants such as pigment which is ionized and dissolved into the liquid crystals 20.

FIG. 4 shows a sectional view of a pixel region to which two video signals are applied and which is interposed between two neighboring drain electrodes 52. The first transparent electrode 70 is formed so as to cover the entire surface including the neighboring drain electrodes 52 under the second insulating film 46 having low permittivity and is held at the common potential. Therefore, the first transparent electrode 70 is able to shield all noise electric fields from the drain electrodes 52. The second transparent electrode 80 is formed on the third insulating film 48 in a slit-like shape, and a pixel potential is applied thereto. An electric field from the second transparent electrode 80 passes through the liquid crystals 20 and reaches the first transparent electrode 70 having the common potential and disposed thereunder through the third insulating film 48.

Since the first transparent electrode 70 blocks the noise electric field from the drain electrodes 52, the pixel electrodes constituted by the neighboring second transparent electrodes 80 with the drain electrode 52 interposed therebetween can be arranged at intervals of the minimum pitch, and a high aperture ratio can be realized. That is, the black matrix 130 can be formed with the minimum width.

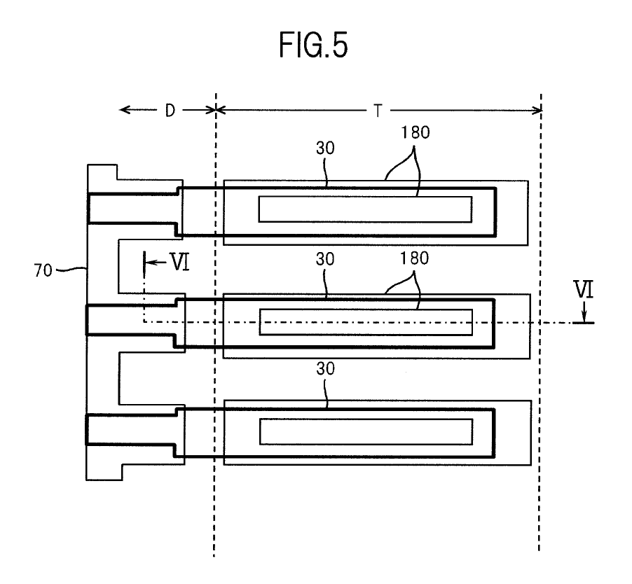

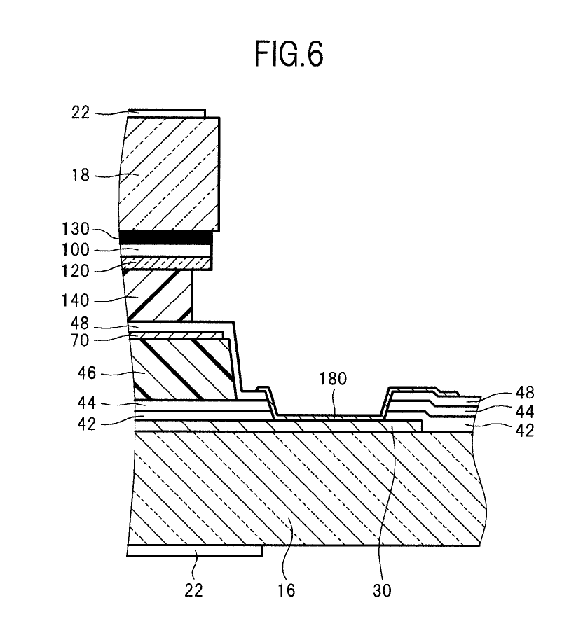

FIG. 5 is a diagram showing a top view pattern of the terminal portions of the gate electrodes 30 in the present embodiment and the vicinities thereof. FIG. 6 is a sectional view of one gate electrode 30 taken along the line VI-VI shown in FIG. 5.

In FIG. 5, the top view pattern of the terminal portions of the gate electrodes 30 shows the gate electrodes 30 of the three consecutive pixels. Connection with an external circuit is achieved in a terminal region T, and specifically, the liquid crystal display panel 10 is connected to a flexible wiring board (not shown) by a mounting method such as COF (Chip-On-Film). The gate voltage is applied from the flexible wiring board to the gate electrodes 30, and this voltage drives and controls the thin-film transistor.

As shown in FIG. 6, in the terminal region T, on the gate electrode 30, an opening is formed in an insulating film which is formed from inorganic material which includes the gate insulating film 42, the first insulating film 44, and the third insulating film 48. A second transparent electrode 180 extends so as to close the opening and cover the gate electrode 30. The second transparent electrode 180 is connected to a flexible wiring board (not shown). In a display region D, the gate electrode 30 is disposed on the first substrate 16 facing the second substrate 18, and the second insulating film 46 and the first transparent electrode 70 are sequentially disposed thereon. In the terminal region T, the second insulating film 46 is removed with the first transparent electrode 70 used as a mask. The first substrate 16 and the second substrate 18 are attached by a sealing material 140 such as an organic adhesive material so that the liquid crystals 20 do not leak.

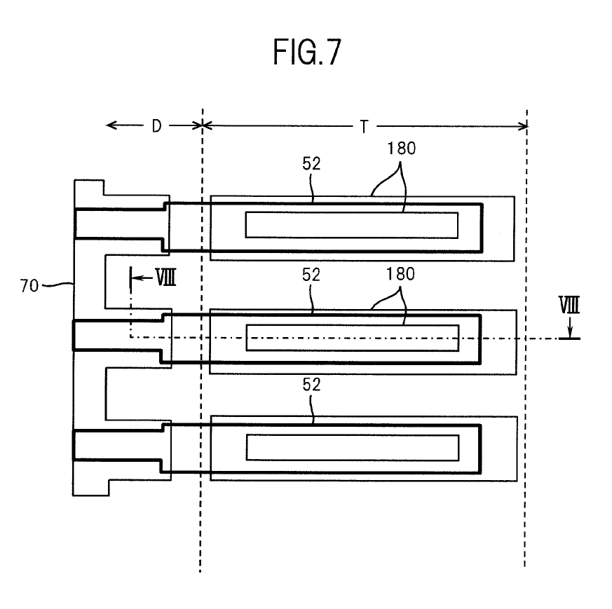

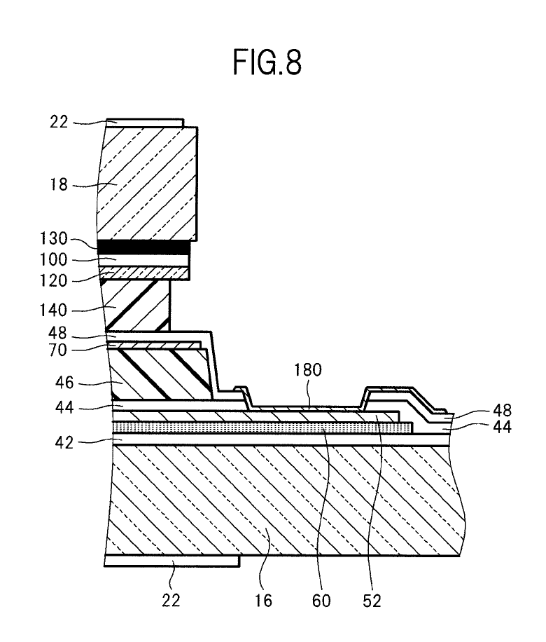

FIG. 7 is a diagram showing the top view pattern of the terminal portions of the drain electrodes 52 in the present embodiment and the vicinities thereof. FIG. 8 is a sectional view of one drain electrode 52 taken along the line VIII-VIII in FIG. 7.

In FIG. 7, the top view pattern of the terminal portion of the drain electrodes 52 shows the drain electrodes 52 of the three consecutive pixels. Connection with an external circuit is achieved in a terminal region T, and specifically, the liquid crystal display panel 10 is connected to a flexible wiring board (not shown) by a mounting method such as COF (Chip-On-Film). The video signal voltage is applied from the flexible wiring board to the drain electrodes 52, and when the thin-film transistor is turned ON, this voltage is transmitted to the source electrode 54 and applied to the second transparent electrode 80 to be transmitted to the display region.

As shown in FIG. 8, in the terminal region T, on the drain electrode 52, an opening is formed in an insulating film which is formed from inorganic material which includes the first insulating film 44 and the third insulating film 48. The second transparent electrode 180 extends so as to close the opening and covers the drain electrode 52. The second transparent electrode 80 is connected to a flexible wiring board (not shown). In the display region D, the drain electrode 52 is disposed on the first substrate 16 facing the second substrate 18, and the second insulating film 46 and the first transparent electrode 70 are sequentially disposed thereon. In the terminal region T, the second insulating film 46 is removed with the first transparent electrode 70 used as a mask. The first substrate 16 and the second substrate 18 are attached by the sealing material 140 such as an organic adhesive material so that the liquid crystals 20 do not leak.

### [Liquid Crystal Display Device Manufacturing Method]

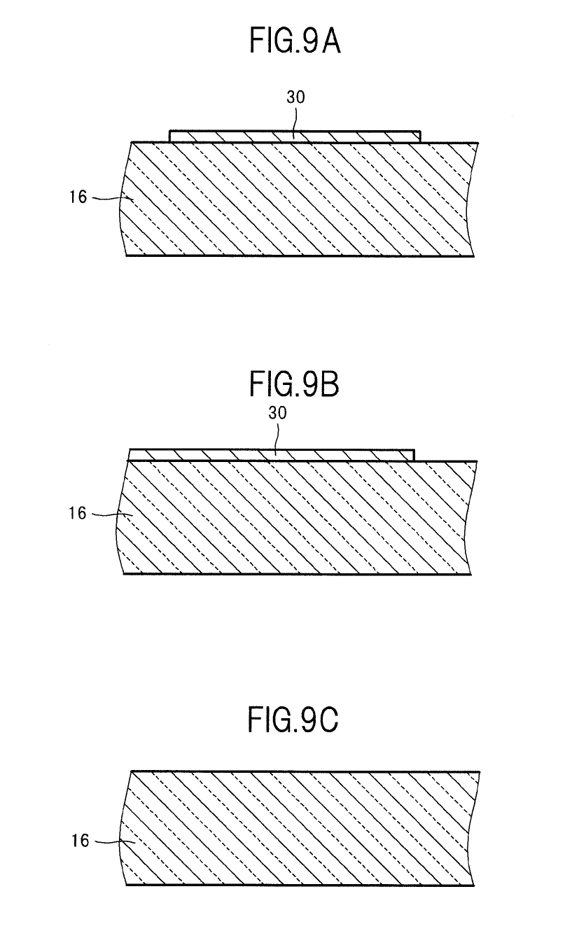

FIGS. 9A to 9C to FIGS. 17A to 17C are diagrams illustrating a method for manufacturing a liquid crystal display device according to the embodiment of the present invention. In these diagrams, FIGS. 9A to 17A show the cross section of the pixel region, FIGS. 9B to 17B show the cross section of a region that forms the terminal portions of the gate electrodes 30, and FIGS. 9C to 17C show the cross section of a region that forms the terminal portions of the drain electrodes 52.

In the present embodiment, a series of processes which include coating of a photoresist, forming of an etching resist from the photoresist by patterning including exposure using a photomask, dry-etching with reactive gas or wet-etching with etching solution, and removal of the etching resist (photoresist) are referred to as photolithography processes.

FIGS. 9A to 9C show the cross section of a structure after an etching resist is removed by a first photolithography process which is performed when TFTs are formed on the first substrate 16. In this process, a conductive film made from Cu (copper) is formed, or a conductive film including an upper Cu film and a lower Mo (molybdenum) film is formed by a sputtering method. A photoresist is coated on the conductive film, and this conductive film is subjected to exposure and development using a first photomask to form an etching resist. The conductive film is etched by wet-etching using the etching resist as a mask, and the etching resist is removed. The conductive film serves as the gate electrode 30.

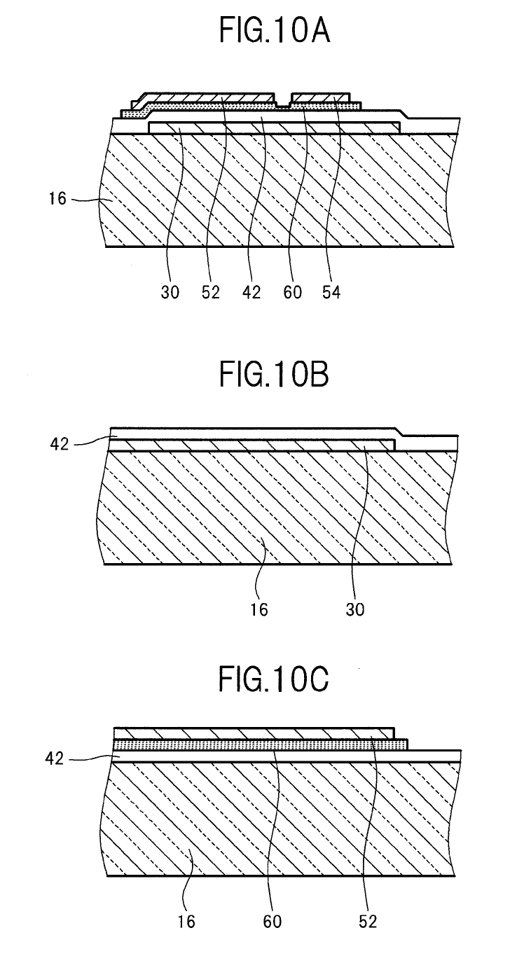

FIGS. 10A to 10C show the cross section of a structure after removal of the etching resist in a second photolithography process is completed. In this process, SiN (silicon nitride), hydrogenated amorphous silicon, phosphorus-doped hydrogenated amorphous silicon are continuously coated on the gate electrode 30 within the same machine by a plasma CVD method. The SiN forms the gate insulating film 42, the hydrogenated amorphous silicon forms the semiconductor layer 60. A conductive material such as Cu or a laminated film of Cu and Mo is coated thereon by a sputtering method.

Subsequently, a photoresist (not shown) is coated, and this coated structure is subjected to exposure using a second photomask. As the photomask, a half-exposure mask having two different transmittances is used. That is, the photomask has a perfect light-blocking region and a thin-metal region (half-exposure region) transmitting half of the light. The half-exposure region is used to form a channel region for the drain electrode 52 and source electrode 54 of the TFT. In the half-exposure region, the thickness of a portion corresponding to the photoresist after the exposure and development of the photoresist is set to approximately half of the original thickness. In this way, an etching resist having a thin portion and a thick portion is formed.

Using the etching resist as a mask, Cu (or the conductive material in which Cu and Mo are laminated) is etched by wet-etching. Further, the semiconductor layer 60 is selectively etched on the gate insulating film 42 by dry-etching.

Subsequently, the etching resist (photoresist) is subjected to ashing, and a portion (thin portion) which has been half-exposed is removed so that only the thick portion remains. Using this etching resist as a mask, wet-etching is performed again so as to remove Cu (or the conductive material in which Cu and Mo are laminated). Further, dry-etching is performed again so as to remove only phosphorus-containing hydrogenated amorphous silicon, and the source electrode 54 is separated from the drain electrode 52. In this way, a thin-film transistor including the gate electrode 30, the drain electrode 52, and the source electrode 54 is formed. As shown in FIG. 10A, in the terminal portion of the gate electrode 30, the entire material (Cu or the like) of the drain electrode 52 and the semiconductor layer 60 are removed.

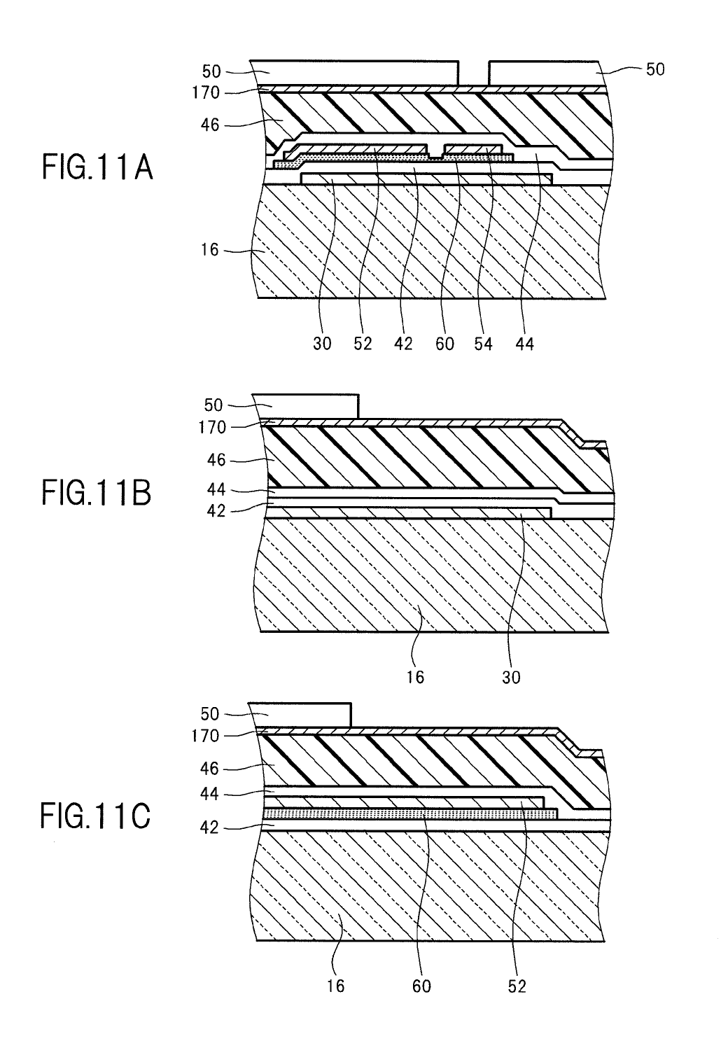

Subsequently, a third photolithography process is performed. As shown in FIG. 11A, SiN is coated on the drain electrode 52 by a plasma CVD method. That is, the first insulating film 44 is formed so as to cover the thin-film transistor. The first insulating film 44 is mainly composed of inorganic material. The first insulating film 44 functions as a protective insulating film and prevents entrance of moisture or the like into the TFT. Subsequently, the second low-permittivity insulating film 46 having low relative permittivity of 4 or lower is coated. That is, the second insulating film 46 is formed on the first insulating film 44. The second insulating film 46 is mainly composed of organic material. Further, a transparent conductive film 170 is formed on the second insulating film 46 by a sputtering method or the like. The transparent conductive film 170 is generally formed from an ITO. A photoresist (not shown) is coated on the transparent conductive film 170, and this coated film is subjected to exposure and development using a third photomask to form an etching resist 50. That is, the etching resist 50 which is patterned by photolithography is formed on the transparent conductive film 170.

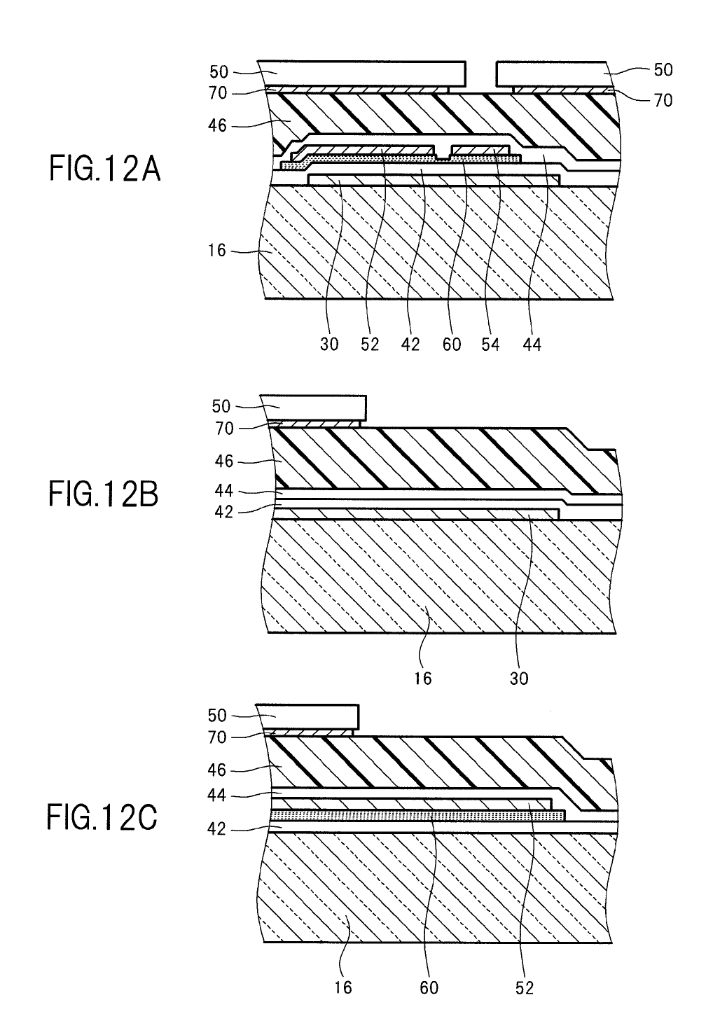

As shown in FIGS. 12A to 12C, an opening is formed in the transparent conductive film 170 by wet-etching, whereby the first transparent electrode 70 is formed. That is, the transparent conductive film 170 is patterned by first etching using the etching resist 50 so as to form the first transparent electrode 70.

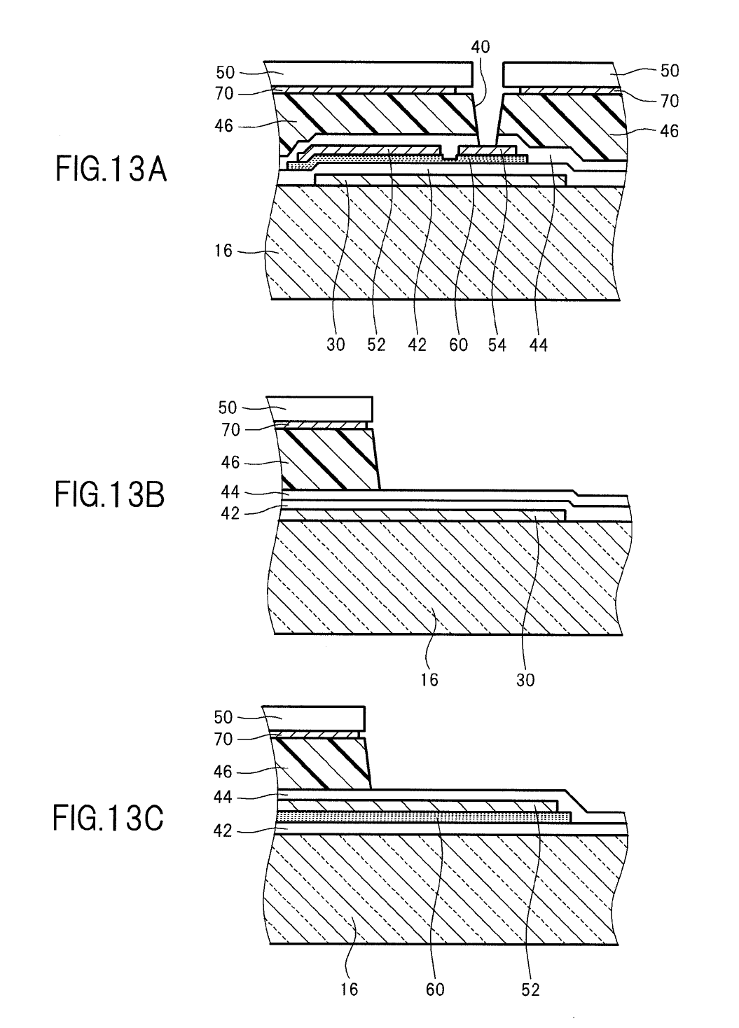

As shown in FIGS. 13A to 13C, a part of the second insulating film 46 is removed so as to conform to the shape of the etching resist 50 by ashing. In this case, the first insulating film 44 is not etched by the ashing. More specifically, a penetration hole 40 is formed in the second insulating film 46 at a position above one of the drain electrode 52 and the source electrode 54 by second etching which is performed using the etching resist 50 on the surface of the second insulating film 46 exposed from the first transparent electrode 70. The second etching is selective etching where the amount of etching on the second insulating film 46 is larger than the amount of etching on the first insulating film 44. The second etching stops before the first insulating film 44 is penetrated.

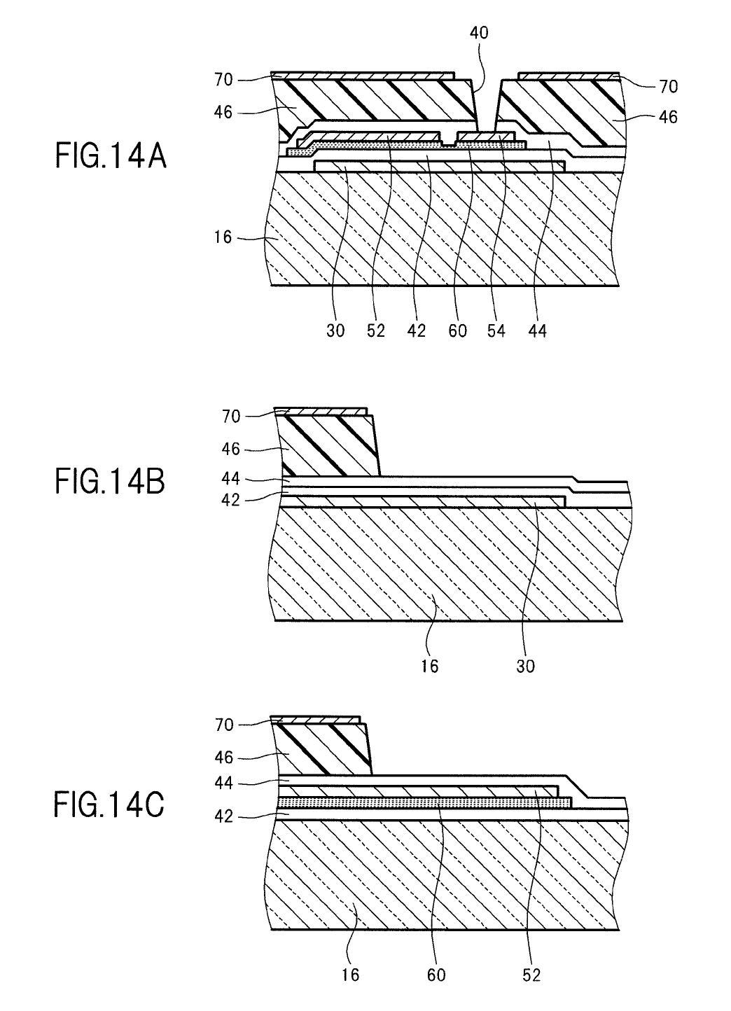

In this way, the etching resist 50 is removed as shown in FIGS. 14A to 14C.

According to the present embodiment, the two processes of patterning the transparent conductive film 170 and forming the penetration hole 40 of the second insulating film 46 are performed using the same etching resist 50. Thus, the photolithography processes can be reduced.

According to the liquid crystal display device manufacturing method of the present embodiment, since the two films, the first transparent electrode 70 and the second insulating film 46, are processed using the etching resist 50 used for forming the first transparent electrode 70, it is possible to simplify the processes. Therefore, the manufacturing cost of a liquid crystal display device having a high aperture ratio and a high luminance can be reduced.

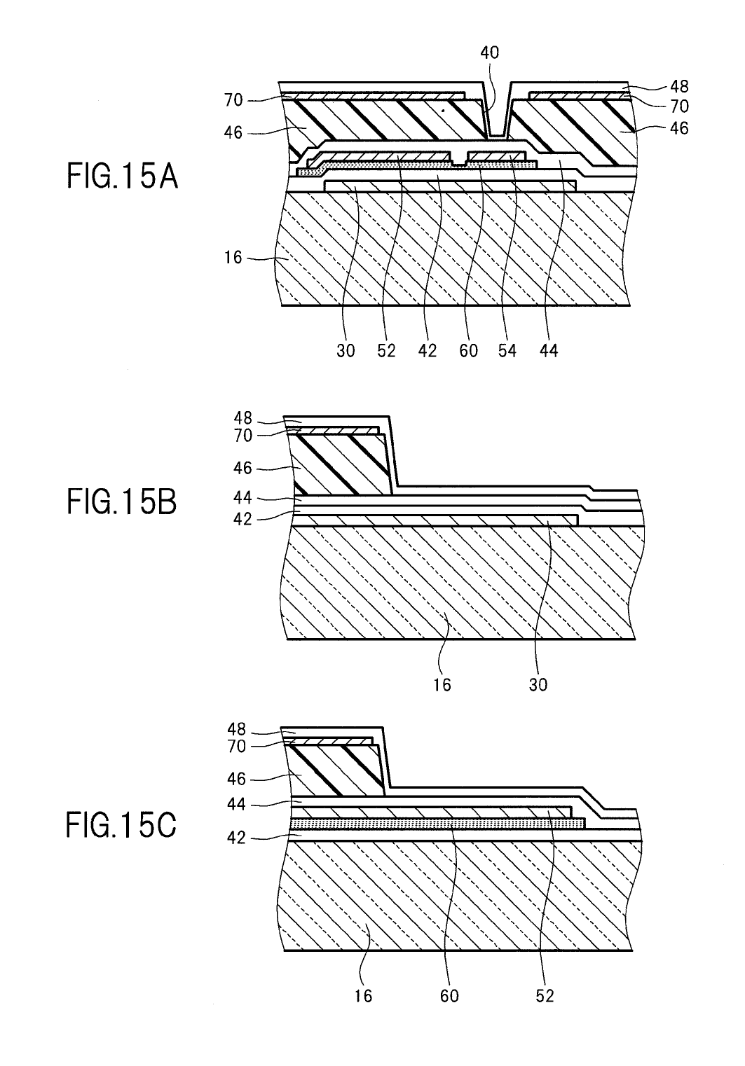

Subsequently, a fourth photolithography process is performed. As shown in FIGS. 15A to 15C, the third insulating film 48 made from SiN is coated on the first transparent electrode 70 by a plasma CVD method. That is, the third insulating film 48 is formed on the first transparent electrode 70, the inner side of the penetration hole 40, and the surface of the first insulating film 44 exposed to the inner side of the penetration hole 40. Then, a photoresist (not shown) is coated on the third insulating film 48, and this coated film is subjected to exposure and development using a fourth photomask.

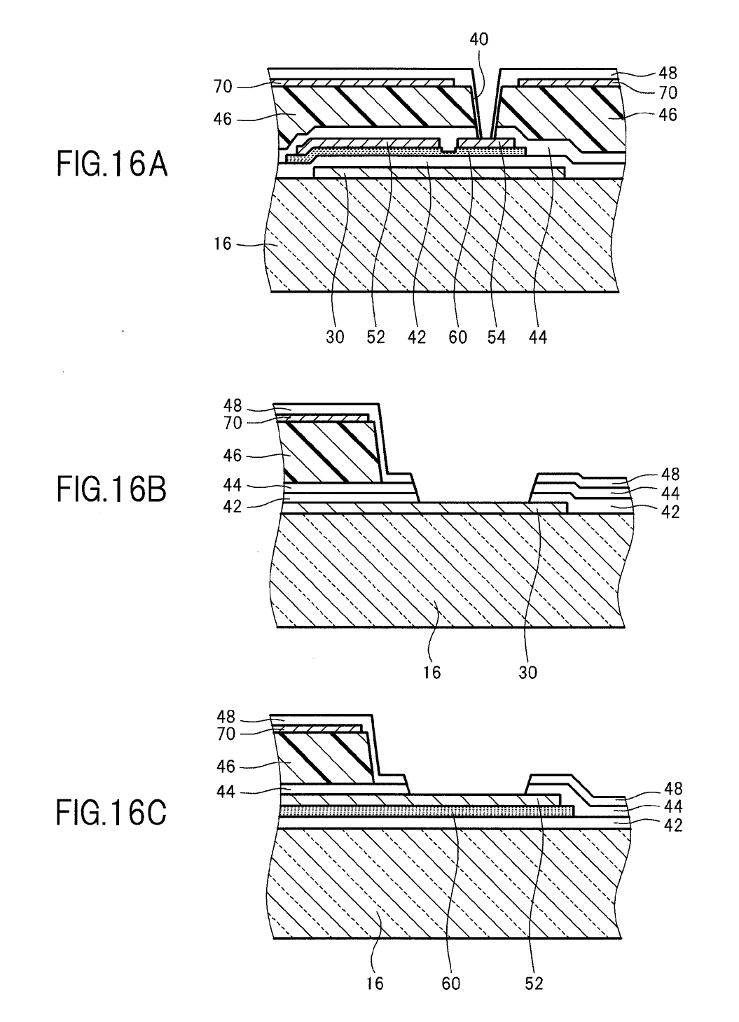

As shown in FIG. 16A, on the inner side of the penetration hole 40, the third insulating film 48 and the first insulating film 44 are etched so as to expose one of the drain electrode 52 and the source electrode 54. As shown in FIG. 16B, in the terminal portion of the gate electrode 30, an opening is formed through the third insulating film 48, the first insulating film 44, and the gate insulating film 42 by dry-etching. As shown in FIG. 16C, in the terminal portion of the drain electrode 52, an opening is formed through the third insulating film 48 and the first insulating film 44 by dry-etching.

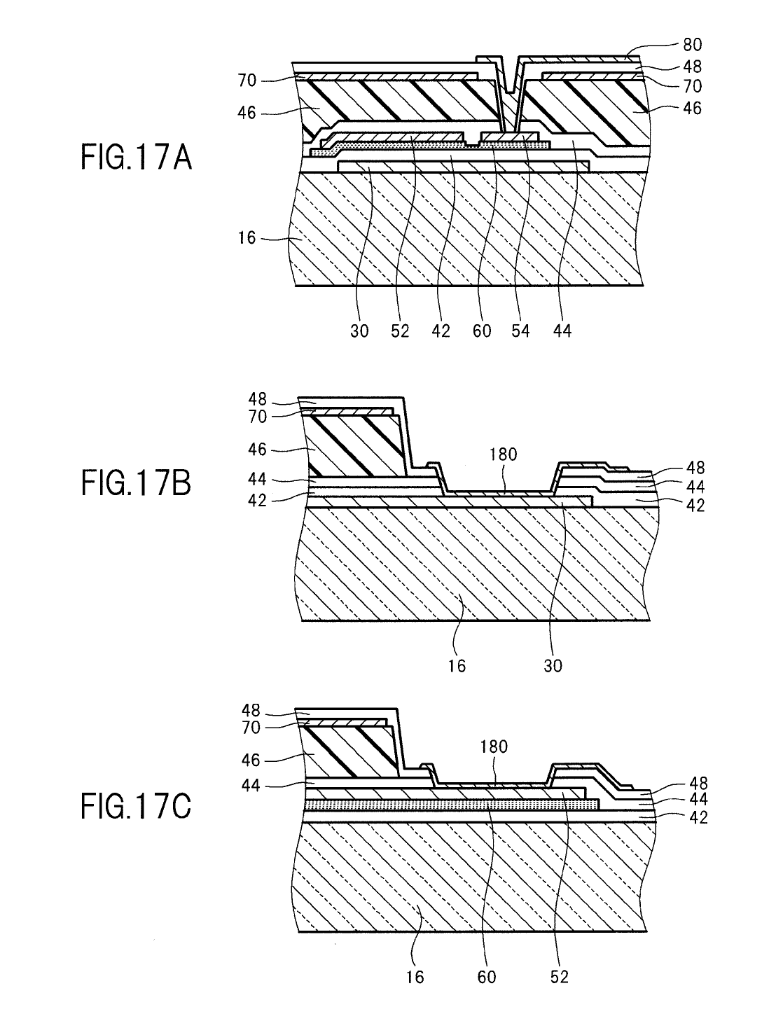

FIGS. 17A to 17C are sectional views of a structure after a resist is removed in a fifth photolithography process. A transparent conductive film is coated on the third insulating film 48 by a sputtering method. A photoresist is coated, and this coated structure is subjected to exposure and development using a fifth photomask to form an etching resist. Using this etching resist as a mask, the second transparent electrodes 80 and 180 are etched. More specifically, the second transparent electrode 80 is formed on a portion of one of the drain electrode 52 and the source electrode 54 exposed from the penetration hole 40 and on the third insulating film 48. As shown in FIG. 17A, in the pixel region, the second transparent electrode 80 functions as the pixel electrode. As shown in FIGS. 17B and 17C, in the terminal portion, the second transparent electrode 180 functions as a terminal electrode to which a voltage from an external driver circuit is supplied.

In the present embodiment, a thin film pattern for a liquid crystal display device having a high aperture ratio is formed on the first substrate 16 using five photolithography processes. In addition, the liquid crystal display device of the present embodiment has a wide viewing field angle performance where liquid crystals are operated by being rotated in accordance with a so-called transverse electric field.

The liquid crystal display device of the present embodiment further includes the configurations (for example, an alignment film) of the known liquid crystal display device, and detailed description thereof will be omitted.

The present invention is not limited to the embodiment described above but can be modified in various ways. For example, the configurations described in the embodiment can be substituted with substantially the same configurations, configurations capable of achieving the same operations and effects, or configurations capable of attaining the same object.

What is claimed is:

1. A liquid crystal display device manufacturing method comprising:
forming a thin-film transistor including a gate electrode, a drain electrode, and a source electrode;
forming a first insulating film so as to cover the thin-film transistor;
forming a second insulating film on the first insulating film;
forming a transparent conductive film on the second insulating film;
forming an etching resist which is patterned by a photolithography process on the transparent conductive film;
forming a first transparent electrode by patterning the transparent conductive film by first etching using the etching resist;
forming a penetration hole in the second insulating film at a position above one of the drain electrode and the source electrode by second etching which is performed using the etching resist on a surface of the second insulating film exposed from the first transparent electrode; and
removing the etching resist.

2. The liquid crystal display device manufacturing method according to claim 1,
wherein the first insulating film is mainly composed of inorganic material, and
wherein the second insulating film is mainly composed of organic material.

3. The liquid crystal display device manufacturing method according to claim 1,
wherein the second etching is selective etching where the amount of etching on the second insulating film is larger than the amount of etching on the first insulating film, and
wherein the second etching stops before the first insulating film is penetrated.

4. The liquid crystal display device manufacturing method according to claim 2,
wherein the second etching is selective etching where the amount of etching on the second insulating film is larger than the amount of etching on the first insulating film, and
wherein the second etching stops before the first insulating film is penetrated.

5. The liquid crystal display device manufacturing method according to claim 3,
after the step of removing the etching resist, further comprising:
forming a third insulating film on the first transparent electrode, an inner side of the penetration hole, and a surface of the first insulating film exposed to the inner side of the penetration hole;
etching the third insulating film and the first insulating film on the inner side of the penetration hole so as to expose one of the drain electrode and the source electrode; and
forming a second transparent electrode on a portion of one of the drain electrode and the source electrode exposed from the penetration hole and on the third insulating film.

6. The liquid crystal display device manufacturing method according to claim 4,
after the step of removing the etching resist, further comprising:
forming a third insulating film on the first transparent electrode, an inner side of the penetration hole, and a surface of the first insulating film exposed to the inner side of the penetration hole;
etching the third insulating film and the first insulating film on the inner side of the penetration hole so as to expose one of the drain electrode and the source electrode; and
forming a second transparent electrode on a portion of one of the drain electrode and the source electrode exposed from the penetration hole and on the third insulating film.

7. The liquid crystal display device manufacturing method according to claim 1,
wherein the first etching is wet-etching.

8. The liquid crystal display device manufacturing method according to claim 1,
wherein the second etching is ashing.

9. The liquid crystal display device manufacturing method according to claim 2,
wherein the first etching is wet-etching.

10. The liquid crystal display device manufacturing method according to claim 2,
wherein the second etching is ashing.
